(19) United States
(12) Patent Application Publication
(10) Pub. No.: US 2024/0364309 A1
(43) Pub. Date: Oct. 31, 2024

(54) ACOUSTICALLY SWITCHED RADIO FREQUENCY FRONTEND CIRCUIT

(71) Applicant: Qorvo US, Inc., Greensboro, NC (US)

(72) Inventor: Nadim Khlat, Cugnaux (FR)

(21) Appl. No.: 18/616,807

(22) Filed: Mar. 26, 2024

Related U.S. Application Data
(60) Provisional application No. 63/498,568, filed on Apr. 27, 2023.

(51) Int. Cl. H03H 9/64; H03H 3/08; H03H 9/145; H03H 9/25; H04B 1/40

(52) U.S. Cl. CPC H03H 9/64; H03H 3/08; H03H 9/145; H03H 9/25; H04B 1/40

(57) ABSTRACT

An acoustically switched radio frequency (RF) frontend circuit is provided. The acoustically switched RF frontend circuit includes multiple acoustic filter circuits each configured to pass an RF signal in a respective one of multiple passbands. In embodiments disclosed herein, a set of acoustic switch circuits is used to replace conventional RF switches, such as transformers, silicon-on-insulator (SOI) switches, and microelectromechanical systems (MEMS) switches. Each of the acoustic switch circuits can be acoustically turned on and off to provide the RF signal to a respective one of the acoustic filter circuits. By replacing the conventional switches with the acoustic switch circuits, it is possible to reduce insertion loss and improve overall performance of the acoustically switched RF frontend circuit.

### RELATED APPLICATIONS

This application claims the benefit of U.S. provisional patent application Ser. No. 63/498,568, filed on Apr. 27, 2023, the disclosure of which is hereby incorporated herein by reference in its entirety.

### FIELD OF THE DISCLOSURE

The technology of the disclosure relates generally to an acoustic radio frequency (RF) frontend circuit.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as surface acoustic wave (SAW) resonators and bulk acoustic wave (BAW) resonators, are used in many high-frequency communication applications. In particular, SAW resonators are often employed in filter networks that operate at frequencies up to 1.8 GHZ, and BAW resonators are often employed in filter networks that operate at frequencies above 1.5 GHZ. Such filters need to have flat passbands, have steep filter skirts and squared shoulders at the upper and lower ends of the passbands, and provide excellent rejection outside of the passbands. SAW and BAW-based filters also have relatively low insertion loss, tend to decrease in size as the frequency of operation increases, and are relatively stable over wide temperature ranges.

As such, SAW and BAW-based filters are the filters of choice for Fifth Generation (5G) and 5G new radio (5G-NR) wireless devices. While these demands keep raising the complexity of wireless devices, there is a constant need to improve the performance of acoustic filters and radio frequency (RF) frontend circuits incorporating the acoustic filters.

### SUMMARY

Aspects disclosed in the detailed description include an acoustically switched radio frequency (RF) frontend circuit. The acoustically switched RF frontend circuit includes multiple acoustic filter circuits each configured to pass an RF signal in a respective one of multiple passbands. In embodiments disclosed herein, a set of acoustic switch circuits is used to replace conventional RF switches, such as transformers, silicon-on-insulator (SOI) switches, and microelectromechanical systems (MEMS) switches. Each of the acoustic switch circuits can be acoustically turned on and off to provide the RF signal to a respective one of the acoustic filter circuits. By replacing the conventional switches with the acoustic switch circuits, it is possible to reduce insertion loss and improve overall performance of the acoustically switched RF frontend circuit.

In one aspect, an acoustically switched RF frontend circuit is provided. The acoustically switched RF frontend circuit includes multiple acoustic filter circuits. Each of the multiple acoustic filter circuits is configured to pass an RF signal in a respective one of multiple passbands. The acoustically switched RF frontend circuit also includes multiple acoustic structures. Each of the multiple acoustic structures includes at least one acoustic switch circuit. The at least one acoustic switch circuit is coupled to a respective one of the multiple acoustic filter circuits and is configured to receive a differential input of the RF signal and output the RF signal to the respective one of the multiple acoustic filter circuits in response to receiving a switching voltage.

In another aspect, a wireless device is provided. The wireless device includes transmit circuitry, receive circuitry, and antenna switching circuitry. The antenna witching circuitry is coupled to the transmit circuitry and the receive circuitry. The wireless device also includes an acoustically switched RF frontend circuit. The acoustically switched RF frontend circuit is provided in any one or more of the transmit circuitry, the receive circuitry, and the antenna switching circuitry. The acoustically switched RF frontend circuit includes multiple acoustic filter circuits. Each of the multiple acoustic filter circuits is configured to pass an RF signal in a respective one of multiple passbands. The acoustically switched RF frontend circuit also includes multiple acoustic structures. Each of the multiple acoustic structures includes at least one acoustic switch circuit. The at least one acoustic switch circuit is coupled to a respective one of the multiple acoustic filter circuits and is configured to receive a differential input of the RF signal and output the RF signal to the respective one of the multiple acoustic filter circuits in response to receiving a switching voltage.

In another aspect, a method for configuring an acoustically switched RF frontend circuit is provided. The method includes configuring multiple acoustic filter circuits to each pass an RF signal in a respective one of multiple passbands. The method also includes providing at least one acoustic switch circuit in each of multiple acoustic structures coupled to a respective one of the multiple acoustic filter circuits. The method also includes receiving, in the at least one acoustic switch circuit, a differential input of the RF signal. The method also includes outputting, from the at least one acoustic switch circuit, the RF signal to the respective one of the multiple acoustic filter circuits in response to receiving a switching voltage.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary conventional surface acoustic wave (SAW) device;

FIG. 2 is a schematic diagram of an exemplary acoustically switched radio frequency (RF) frontend circuit configured according to an embodiment of the present disclosure;

FIG. 3 is a schematic diagram of an exemplary acoustically switched RF frontend circuit configured according to another embodiment of the present disclosure;

FIGS. 4A and 4B are schematic diagrams of exemplary acoustic switch circuits configured according to various embodiments of the present disclosure to enable acoustic switching in the acoustically switched RF frontend circuits in FIGS. 2 and 3;

FIG. 5 is a schematic diagram of an exemplary acoustic switch that can be employed in the acoustic switch circuits of FIGS. 4A and 4B;

FIG. 6 is a schematic diagram of an exemplary communication device wherein the acoustically switched RF frontend circuits of FIGS. 2 and 3 can be provided; and

FIG. 7 is a schematic diagram for configuring the acoustically switched RF frontend circuits of FIGS. 2 and 3.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an acoustically switched radio frequency (RF) frontend circuit. The acoustically switched RF frontend circuit includes multiple acoustic filter circuits each configured to pass an RF signal in a respective one of multiple passbands. In embodiments disclosed herein, a set of acoustic switch circuits is used to replace conventional RF switches, such as transformers, silicon-on-insulator (SOI) switches, and microelectromechanical systems (MEMS) switches. Each of the acoustic switch circuits can be acoustically turned on and off to provide the RF signal to a respective one of the acoustic filter circuits. By replacing the conventional switches with the acoustic switch circuits, it is possible to reduce insertion loss and improve overall performance of the acoustically switched RF frontend circuit.

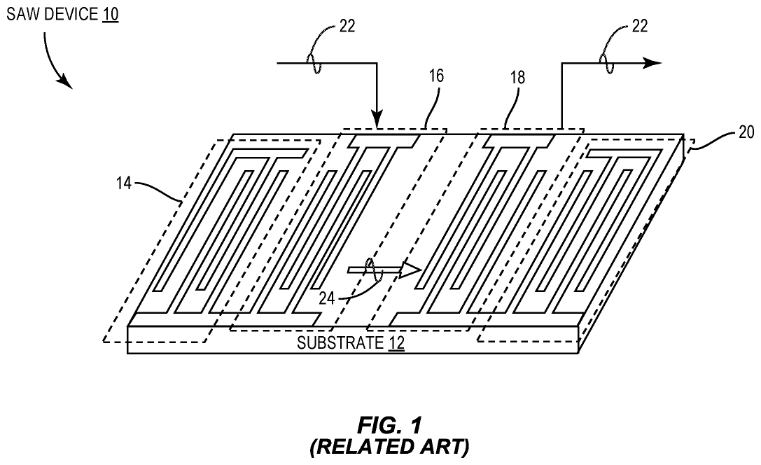

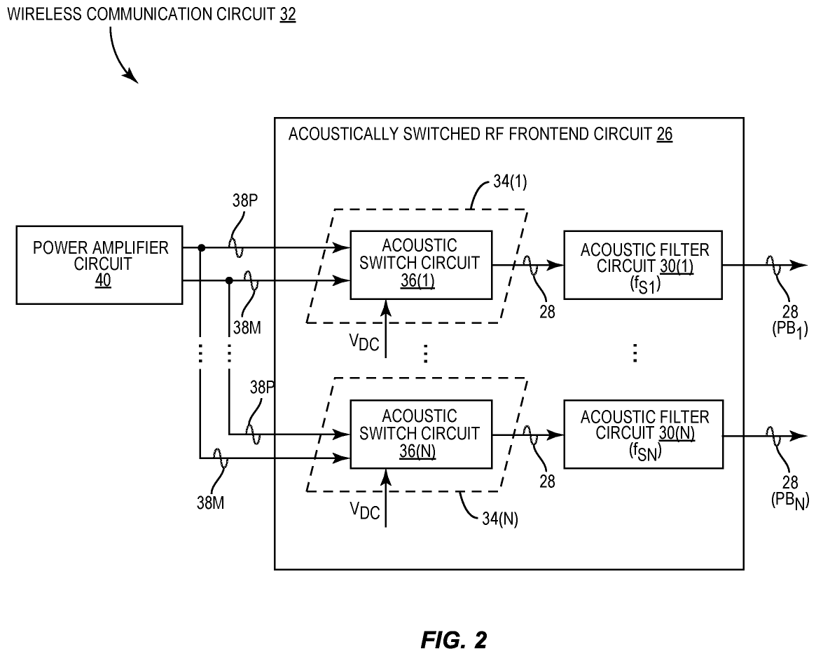

Before discussing the acoustically switched RF frontend circuit of the present disclosure, starting at FIG. 2, a brief discussion of a conventional surface acoustic wave (SAW) device is first provided with reference to FIG. 1 to help understand how an acoustic switch circuit in the acoustically switched RF frontend circuit can be constructed from the conventional SAW device.

FIG. 1 is a schematic diagram of an exemplary conventional SAW device 10. The conventional SAW device 10 is typically constructed on a substrate 12 (e.g., a piezoelectric substrate). The conventional SAW device 10 includes an input reflector 14, an input interdigital transducer (IDT) 16, an output IDT 18, and an output reflector 20, which are arranged as illustrated. The input IDT 16 converts an electrical signal 22 (e.g., an RF signal) into a SAW 24, which propagates from the substrate 12 to the output IDT 18. The output IDT 18, in turn, converts the SAW 24 back to the electrical signal 22 and outputs the electrical signal 22 thereon. As further described later, the conventional SAW device 10 can be reconfigured according to embodiments of the present disclosure to construct an acoustic switch in an acoustically switched RF frontend circuit.

FIG. 2 is a schematic diagram of an exemplary acoustically switched RF frontend circuit 26 configured according to an embodiment of the present disclosure to switch an RF signal 28 between multiple acoustic filter circuits 30(1)-30(N) in a wireless communication circuit 32. In an embodiment, each of the acoustic filter circuits 30(1)-30(N) can be a bulk acoustic wave (BAW) acoustic ladder network configured to resonate in a respective one of multiple series resonance frequencies fₛ₁-f_{sN} to pass the RF signal 28 in a respective one of multiple passbands PB₁-PB_{N}. Each of the acoustic filter circuits 30(1)-30(N) is further configured to block the RF signal 28 outside the respective one of the passbands PB₁-PB_{N}.

The acoustically switched RF frontend circuit 26 includes multiple acoustic structures 34(1)-34(N). Each of the acoustic structures 34(1)-34(N) is coupled to a respective one of the acoustic filter circuits 30(1)-30(N). Herein, the acoustic structures 34(1)-34(N) are configured to replace such conventional RF switches as transformers, SOI switches, and MEMS switches to not only switch the RF signal 28 between the acoustic filter circuits 30(1)-30(N) but also to significantly reduce the insertion loss of the conventional RF switches. As a result, it is possible to improve overall performance of the wireless communication circuit 32.

According to one embodiment of the present disclosure, each of the acoustic structures 34(1)-34(N) includes a respective one of multiple acoustic switch circuits 36(1)-36(N). Each of the acoustic switch circuits 36(1)-36(N) is coupled to the respective one of the acoustic filter circuits 30(1)-30(N) associated with a respective one of the acoustic structures 34(1)-34(N). Each of the acoustic switch circuits 36(1)-36(N) is configured to receive a differential input 38P, 38M of the RF signal 28. Herein, the wireless communication circuit 32 further includes a power amplifier circuit 40 configured to generate and provide the differential input 38P, 38M to each of the acoustic switch circuits 36(1)-36(N) in the acoustically switched RF frontend circuit 26.

Depending on which of the passbands P_{B1}-P_{BN} the RF signal 28 should be transmitted in, one of the acoustic switch circuits 36(1)-36(N) will receive a switching voltage V_{DC} (a.k.a. “turned-on” or “closed”) to pass the RF signal 28 to the respective one of the acoustic filter circuits 30(1)-30(N). In the meantime, other ones of the acoustic switch circuits 36(1)-36(N) will not receive the switching voltage V_{DC} (a.k.a. “turned-off” or “opened”) and, therefore, block the RF signal 28 from the respective ones of the acoustic filter circuits 30(1)-30(N).

In a non-limiting example, the switching voltage V_{DC} can be provided by a transceiver circuit (not shown) that generates the differential input 38P, 38M or by a controller (not shown) in the acoustically switched RF frontend circuit 26 in accordance with instructions received from the transceiver circuit. It should be appreciated that the switching voltage V_{DC} can also be provided by any suitable means without changing the switching operation described herein.

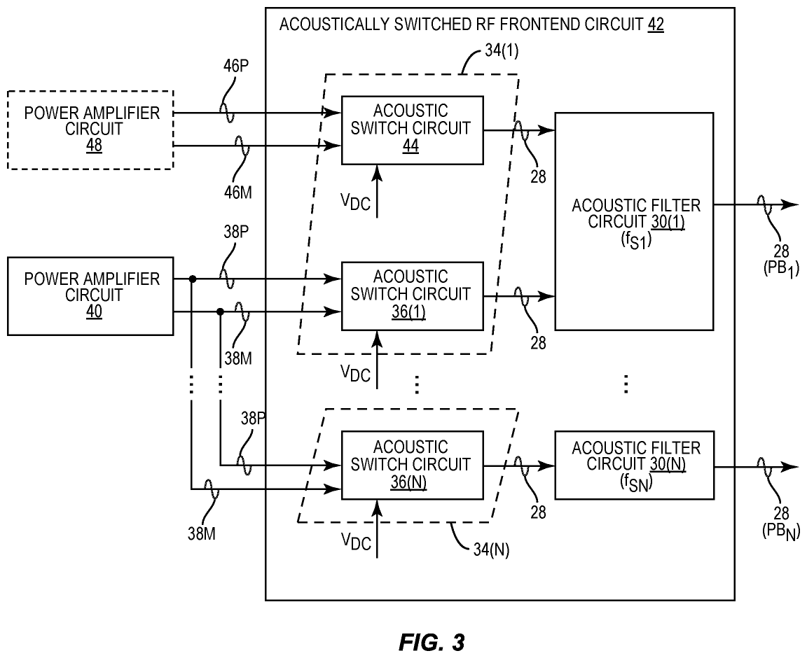

In an alternative embodiment, some or all of the acoustic structures 34(1)-34(N) can include additional acoustic switch circuits. In this regard, FIG. 3 is a schematic diagram of an exemplary acoustically switched RF frontend circuit 42 configured according to another embodiment of the present disclosure. Common elements between FIGS. 2 and 3 are shown therein with common element numbers and will not be re-described herein.

In a non-limiting example, the acoustic structure 34(1) can be configured to include at least one second acoustic switch circuit 44. Like the acoustic switch circuit 36(1), the second acoustic switch circuit 44 is also coupled to the acoustic filter circuit 30(1). It should be appreciated that, any one or more of the acoustic structures 34(1)-34(N) can be configured to include the second acoustic switch circuit 44. The second acoustic switch circuit 44 may receive a second differential input 46P, 46M of the RF signal 28, for example, from a second power amplifier circuit 48, and output the RF signal 28 to the acoustic filter circuit 30(1) in response to receiving the switching voltage V_{DC}. Notably, by including the second acoustic switch circuit 44, it may also be possible to create tunability between different frequency responses.

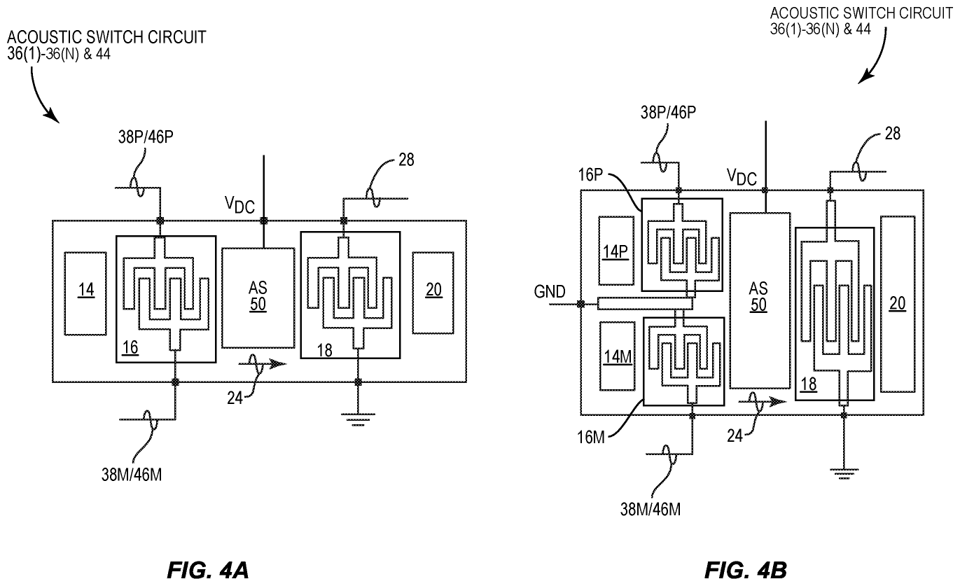

Herein, the acoustic switch circuits 36(1)-36(N) in FIGS. 2 and 3 and the second acoustic switch circuit 44 in FIG. 3 can be SAW acoustic switch circuits implemented based on the conventional SAW device 10 of FIG. 1. FIGS. 4A and 4B are schematic diagrams providing exemplary illustrations of the acoustic switch circuits 36(1)-36(N) and the second acoustic switch circuit 44 in FIGS. 2 and 3 configured according to various embodiments of the present disclosure. Common elements between FIGS. 1, 2, 3, and 4A-4B are shown therein with common element numbers and will not be re-described herein.

With reference to FIG. 4A, as in the conventional SAW device 10 of FIG. 1, the input IDT 16 is configured to convert the differential input 38P, 38M or 46P, 46M into the SAW 24 and the output IDT 18 is configured to convert the SAW 24 into the RF signal 28. Herein, an acoustic switch (AS) 50 is provided between the input IDT 16 and the output IDT 18. The AS 50 is configured to pass the SAW 24 from the input IDT 16 to the output IDT 18 in response to receiving the switching voltage V_{DC} and block the SAW 24 between the input IDT 16 and the output IDT 18 in absence of the switching voltage V_{DC}.

With reference to FIG. 4B, the input reflector 14 in FIG. 4A is replaced by a pair of differential input reflectors 14P, 14M and the input IDT 16 in FIG. 4A is replaced by a pair of differential input IDTs 16P, 16M. Herein, the differential input IDTs 16P, 16M are configured to convert the differential input 38P, 38M or 46P, 46M into the SAW 24. The AS 50 is instead provided between the differential input IDTs 16P, 16M and the output IDT 18. Herein, the AS 50 is configured to pass the SAW 24 from the differential input IDTs 16P, 16M to the output IDT 18 in response to receiving the switching voltage V_{DC} and block the SAW 24 between the differential input IDTs 16P, 16M and the output IDT 18 in absence of the switching voltage V_{DC}.

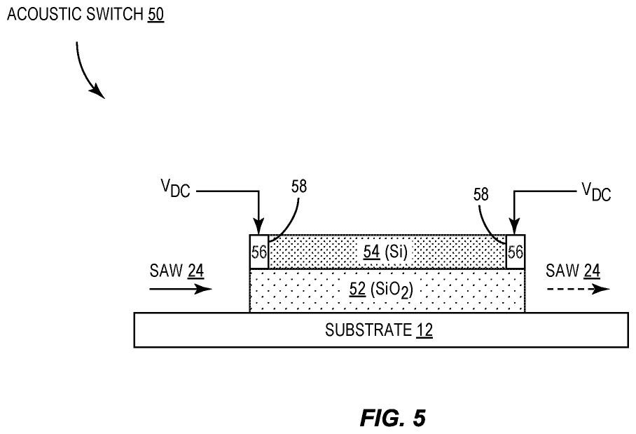

FIG. 5 is a schematic diagram providing an exemplary sideview of the AS 50 configured according to an embodiment of the present disclosure. Herein, the AS 50 can include a silicon dioxide (SiO₂) layer 52 provided on the substrate 12 in FIG. 1 and a silicon (Si) layer 54 provided on the SiO₂ layer 52. The AS 50 also includes a pair of electrodes 56, which are provided on the SiO₂ layer 52 and on both sides of the Si layer 54 to form a pair of lateral sides 58 of the Si layer 56. Herein, the pair of electrodes 56 are configured to receive the switching voltage V_{DC}. When the switching voltage V_{DC} (e.g., 20 V) is applied to the electrode 56, the AS 50 is switched on to pass the SAW 24. Otherwise, the AS 50 is switched off to block the SAW 24.

In an embodiment, the substrate 12 may be a thin-film lithium niobate (LiNbO₃), which has been identified as a high K2 and low-loss shear-horizontal surface acoustic wave (SH-SAW) traveling wave platform. In an embodiment, the pair of electrodes 56 may be each be a cobalt disilicide (CoSi₂) intermetallic compound region.

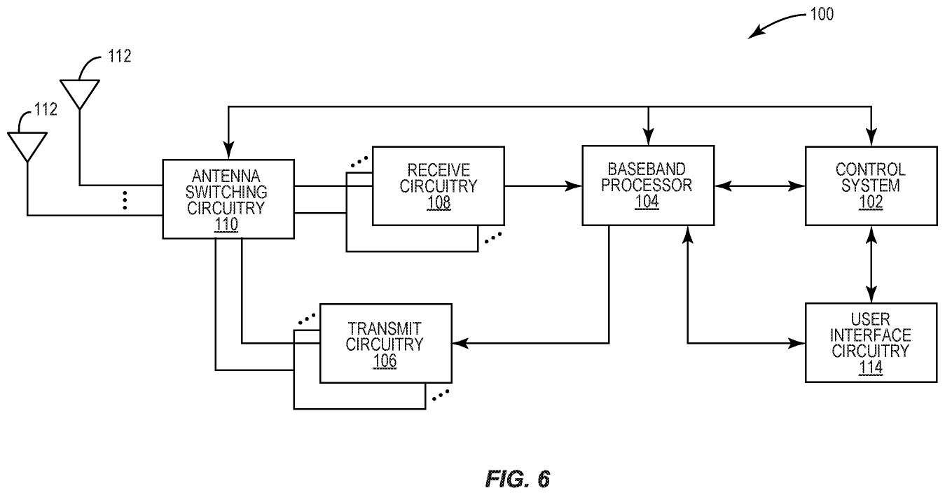

The acoustically switched RF frontend circuit 26 of FIG. 2 and the acoustically switched RF frontend circuit 42 of FIG. 3 can be provided in a communication device to support the embodiments described above. In this regard, FIG. 6 is a schematic diagram of an exemplary communication device 100 wherein the acoustically switched RF frontend circuit 26 of FIG. 2 and the acoustically switched RF frontend circuit 42 of FIG. 3 can be provided.

Herein, the communication device 100 can be any type of communication device, such as mobile terminal, smart watch, tablet, computer, navigation device, access point, base station (e.g., eNB, gNB, etc.), and any other type of wireless communication device that supports wireless communications, such as cellular, wireless local area network (WLAN), Bluetooth, Ultra-wideband (USB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Herein, the acoustically switched RF frontend circuit 26 of FIG. 2 and the acoustically switched RF frontend circuit 42 of FIG. 3 may be provided in the transmit circuitry 106, the receive circuitry 108, and/or the antenna switching circuitry 110. Understandably, the acoustically switched RF frontend circuit 26 of FIG. 2 and the acoustically switched RF frontend circuit 42 of FIG. 3 may also be provided in any other circuitries in the communication device 100.

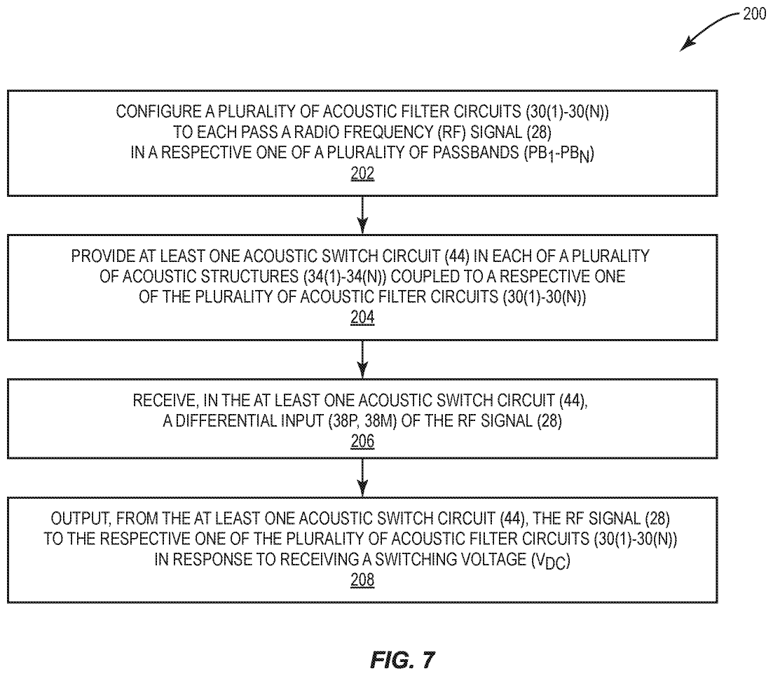

In an embodiment, the acoustically switched RF frontend circuit 32 of FIG. 2 and the acoustically switched RF frontend circuit 42 of FIG. 3 can be configured according to a process. In this regard, FIG. 7 is a flowchart of an exemplary process 200 for configuring the acoustically switched RF frontend circuit 32 of FIG. 2 and the acoustically switched RF frontend circuit 42 of FIG. 3.

Herein, the process 200 includes configuring the acoustic filter circuits 30(1)-30(N) to each pass the RF signal 28 in a respective one of the passbands PB₁-PB_{N} (step 202). The process 200 also includes providing the acoustic switch circuit 44 in each of the acoustic structures 34(1)-34(N) that is coupled to a respective one of the acoustic filter circuits 30(1)-30(N) (step 204). The process 200 also includes receiving, in the acoustic switch circuit 44, the differential input 38P, 38M of the RF signal 28 (step 206). The process 200 also includes outputting, from the acoustic switch circuit 44, the RF signal 28 to the respective one of the acoustic filter circuits 30(1)-30(N) in response to receiving the switching voltage V_{DC} (step 208).

Those skilled in the art will recognize improvements and modifications to the embodiments of the present disclosure. All such improvements and modifications are considered within the scope of the concepts disclosed herein and the claims that follow.

What is claimed is:

1. An acoustically switched radio frequency (RF) frontend circuit comprising:
a plurality of acoustic filter circuits each configured to pass an RF signal in a respective one of a plurality of passbands; and
a plurality of acoustic structures each comprising at least one acoustic switch circuit coupled to a respective one of the plurality of acoustic filter circuits, the at least one acoustic switch circuit is configured to:
receive a differential input of the RF signal; and
output the RF signal to the respective one of the plurality of acoustic filter circuits in response to receiving a switching voltage.

2. The acoustically switched RF frontend circuit of claim 1, wherein at least one of the plurality of acoustic structures comprises a second acoustic switch circuit coupled to the respective one of the plurality of acoustic filter circuits and is configured to:
receive a second differential input of the RF signal; and
output the RF signal to the respective one of the plurality of acoustic filter circuits in response to receiving the switching voltage.

3. The acoustically switched RF frontend circuit of claim 1, wherein the at least one acoustic switch circuit in each of the plurality of acoustic structures comprises:
an input interdigital transducer (IDT) configured to convert the differential input of the RF signal into a surface acoustic wave (SAW);
an output IDT configured to convert the SAW into the RF signal; and
an acoustic switch provided between the input IDT and the output IDT and configured to:
pass the SAW from the input IDT to the output IDT in response to receiving the switching voltage; and
block the SAW between the input IDT and the output IDT in absence of the switching voltage.

4. The acoustically switched RF frontend circuit of claim 3, wherein the acoustic switch comprises:
a substrate;
a silicon dioxide (SiO₂) layer disposed on the substrate;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the switching voltage.

5. The acoustically switched RF frontend circuit of claim 4, wherein:
the substrate is a thin-film lithium niobate (LiNbO₃) substrate; and
each of the pair of electrodes is a cobalt disilicide (CoSi₂) intermetallic compound region.

6. The acoustically switched RF frontend circuit of claim 1, wherein the at least one acoustic switch circuit in each of the plurality of acoustic structures comprises:
a pair of differential input interdigital transducers (IDTs) configured to convert the differential input of the RF signal into a surface acoustic wave (SAW);
an output IDT configured to convert the SAW into the RF signal; and
an acoustic switch provided between the pair of differential input IDTs and the output IDT and configured to:
pass the SAW from the pair of differential input IDTs to the output IDT in response to receiving the switching voltage; and
block the SAW between the pair of differential input IDTs and the output IDT in absence of the switching voltage.

7. The acoustically switched RF frontend circuit of claim 1, wherein the plurality of acoustic filter circuits each comprises a bulk acoustic wave (BAW) acoustic ladder network.

8. A wireless device comprising:
transmit circuitry, receive circuitry, and antenna switching circuitry coupled to the transmit circuitry and the receive circuitry; and
an acoustically switched radio frequency (RF) frontend circuit provided in any one or more of the transmit circuitry, the receive circuitry, and the antenna switching circuitry, the acoustically switched radio frequency (RF) frontend circuit comprises:
a plurality of acoustic filter circuits each configured to pass an RF signal in a respective one of a plurality of passbands; and
a plurality of acoustic structures each comprising at least one acoustic switch circuit coupled to a respective one of the plurality of acoustic filter circuits, the at least one acoustic switch circuit is configured to:
receive a differential input of the RF signal; and
output the RF signal to the respective one of the plurality of acoustic filter circuits in response to receiving a switching voltage.

9. The wireless device of claim 8, wherein at least one of the plurality of acoustic structures comprises a second acoustic switch circuit coupled to the respective one of the plurality of acoustic filter circuits and is configured to:
receive a second differential input of the RF signal; and
output the RF signal to the respective one of the plurality of acoustic filter circuits in response to receiving the switching voltage.

10. The wireless device of claim 8, wherein the at least one acoustic switch circuit in each of the plurality of acoustic structures comprises:
an input interdigital transducer (IDT) configured to convert the differential input of the RF signal into a surface acoustic wave (SAW);
an output IDT configured to convert the SAW into the RF signal; and
an acoustic switch provided between the input IDT and the output IDT and configured to:
pass the SAW from the input IDT to the output IDT in response to receiving the switching voltage; and
block the SAW between the input IDT and the output IDT in absence of the switching voltage.

11. The wireless device of claim 10, wherein the acoustic switch comprises:
a substrate;
a silicon dioxide (SiO₂) layer disposed on the substrate;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the switching voltage.

12. The wireless device of claim 11, wherein:
the substrate is a thin-film lithium niobate (LiNbO₃) substrate; and
each of the pair of electrodes is a cobalt disilicide (CoSi₂) intermetallic compound region.

13. The wireless device of claim 8, wherein the at least one acoustic switch circuit in each of the plurality of acoustic structures comprises:
a pair of differential input interdigital transducers (IDTs) configured to convert the differential input of the RF signal into a surface acoustic wave (SAW);
an output IDT configured to convert the SAW into the RF signal; and
an acoustic switch provided between the pair of differential input IDTs and the output IDT and configured to:
pass the SAW from the pair of differential input IDTs to the output IDT in response to receiving the switching voltage; and
block the SAW between the pair of differential input IDTs and the output IDT in absence of the switching voltage.

14. The wireless device of claim 8, wherein the plurality of acoustic filter circuits each comprises a bulk acoustic wave (BAW) acoustic ladder network.

15. A method for configuring an acoustically switched radio frequency (RF) frontend circuit comprising:
configuring a plurality of acoustic filter circuits to each pass an RF signal in a respective one of a plurality of passbands;
providing at least one acoustic switch circuit in each of a plurality of acoustic structures coupled to a respective one of the plurality of acoustic filter circuits;
receiving, in the at least one acoustic switch circuit, a differential input of the RF signal; and
outputting, from the at least one acoustic switch circuit, the RF signal to the respective one of the plurality of acoustic filter circuits in response to receiving a switching voltage.

16. The method of claim 15, further comprising:
receiving, using a second acoustic switch circuit provided in at least one of the plurality of acoustic structures, a second differential input of the RF signal; and
outputting, from the second acoustic switch circuit, the RF signal to the respective one of the plurality of acoustic filter circuits in response to receiving the switching voltage.

17. The method of claim 15, further comprising constructing the at least one acoustic switch circuit to include:
an input interdigital transducer (IDT) configured to convert the differential input of the RF signal into a surface acoustic wave (SAW);
an output IDT configured to convert the SAW into the RF signal; and
an acoustic switch provided between the input IDT and the output IDT and configured to:
pass the SAW from the input IDT to the output IDT in response to receiving the switching voltage; and
block the SAW between the input IDT and the output IDT in absence of the switching voltage.

18. The method of claim 17, wherein the acoustic switch comprises:
a substrate;
a silicon dioxide (SiO₂) layer disposed on the substrate;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the switching voltage.

19. The method of claim 18, wherein:
the substrate is a thin-film lithium niobate (LiNbO₃) substrate; and
each of the pair of electrodes is a cobalt disilicide (CoSi₂) intermetallic compound region.

20. The method of claim 15, wherein the plurality of acoustic filter circuits each comprises a bulk acoustic wave (BAW) acoustic ladder network.
